(19) United States
(12) Patent Application Publication
(10) Pub. No.: US 2014/0041909 A1
(43) Pub. Date: Feb. 13, 2014

(54) Ceramic Substrate and Method for Reducing Surface Roughness of Metal Filled Via Holes Thereon

(71) Applicant: ECOCERA Optronics., Co., Ltd., Taoyuan (TW)

(72) Inventors: Hsiang-Wei TSENG, Taoyuan (TW); Kuan-Chou Chen, Taoyuan (TW); Han-Chung Chang, Taoyuan (TW); Cheng-Feng Chou, Taouyan (TW); Chan-Li Lin, Taoyuan (TW); Yuan-Chen Hsu, Taoyuan (TW)

(21) Appl. No.: 13/944,673

(22) Filed: Jul. 17, 2013

(30) Foreign Application Priority Data
Aug. 7, 2012 (TW) 101128512

(51) Int. Cl. H05K 3/46; H05K 1/09

(52) U.S. Cl. CPC H05K 3/4644; H05K 1/09
USPC 174/257; 205/125; 430/319

(57) ABSTRACT

A method for reducing roughens of the metals on a ceramic substrate having metal filled via holes, comprising forming via holes, a seed layer, and through film coating, exposure and development process followed by multiple steps of DC electroplating to achieve copper circuit with desired surface roughness.

The current application claims a foreign priority to the patent application of Taiwan No. 101128512 filed on Aug. 7, 2012.

### FIELD OF THE INVENTION

The present invention relates to a ceramic substrate with metal filled via holes and a method for reducing the surface roughness of the metals on the ceramic substrate having via holes, more specifically the present invention relates to a method using multiple steps of direct current electroplating to achieve the desired roughness of the metals on the ceramic substrate having via holes.

### BACKGROUND OF THE INVENTION

In order to meet the requirement of the trend for low-profile electronic product, electronic elements are aimed for high efficiency, high functionality, and high density. The substrate carrying the electronic elements thereon, must also meet the same requirement. As a result of that heat dissipation became an important issue with high attention.

Taking Light-Emitting Diode (LED) as an example, as the technology of LED has advanced greatly in efficiency and functionality, that the application of 7W or even 10W LED die is widely used in the art, as such the ceramic substrate which has much higher dissipation capacity has become the preferable choice as a carrier in order to efficiently dissipate heat during operation of the LED chip, as well as to maintain the operational stability of LED module.

Generally, the fabrication process of a single layered ceramic substrate includes thick film and thin film fabrication. Thin film fabrication has become the best application used in electronic elements with high efficiency and it has several advantages over thick film fabrication, including high circuit precision, high stability of the material, high surface planarity and is not as easily oxidised, as well as better adherence.

The copper circuit of a conventional thin film substrate is fabricated using pulse plating method. However in regard to using pulse elecroplating in LED ceramic substrate, as the efficiency of light reflection and surface roughness is not ideal, subsequently affecting the LED light reflection efficiency, the yield of the LED die package and the stability of the product. In order to achieve better planarity of the circuit and copper surface with higher reflection efficiency, the person skilled in the art usually would use abrasive belt grinding or polishing to improve the quality of the product. However regardless it is grinding or polishing, this additional process increases both the risk of breakage of the substrate and the production cost.

As a result, there is an urinate need in the art to develop a method of reducing metal surface roughness of a ceramic substrate having via holes, used in electronic elements with high efficiency.

### SUMMARY OF THE INVENTION

In order to solve the foregoing drawbacks of the conventional technology, the present invention provides a method for reducing the surface roughness of the metals on the ceramic substrate having via holes. The method includes the steps of: preparing a ceramic substrate; forming at least one of a via hole and a cutting slot on the predetermined position of the ceramic substrate; forming a seed layer on the predetermined position of the ceramic substrate; performing a photolithography step to form a circuit pattern on the seed layer; and, performing multiple steps of direct current electroplating to form a copper circuit on the circuit pattern.

In another embodiment of the present invention, a method for reducing the surface roughness of the metals on the ceramic substrate having via holes is provided. The mentioned method includes the steps of: preparing a ceramic substrate; forming at least one of a via hole and a cutting slot on the predetermined position of the ceramic substrate; forming a seed layer on the predetermined position of the ceramic substrate; using direct current electroplating method or chemical plating to increase the thickness of the seed layer; performing a photolithography step to form a circuit pattern on the seed layer; and, performing multiple steps of direct current electroplating to form a copper circuit on the circuit pattern.

After the steps described in foregoing two embodiments, additional steps can be performed. The mentioned additional steps include: electroplating of nickel on the copper circuit layer and electroplating of silver or gold on the nickel layer, followed by a stripping step and an etching step, for removing unneeded materials other than the copper circuit on the ceramic substrate.

In yet another embodiment of the present invention, a method for reducing the surface roughness of the metals on the ceramic substrate having via holes is provided. The mentioned method includes the steps of: preparing a ceramic substrate; forming at least one of a via hole and a cutting slot on the predetermined position of the ceramic substrate; forming a seed layer on the predetermined position of the ceramic substrate; forming a pattern on the seed layer using a process of film coating, exposure and development; and, performing multiple steps of direct current electroplating to form a copper circuit on the circuit pattern; and performing a process of stripping and etching.

In further another embodiment of the present invention, a method for reducing the surface roughness of the metals on the ceramic substrate having via holes is provided. The mentioned method includes the steps of: preparing a ceramic substrate; forming at least one of a via hole and a cutting slot on the predetermined position of the ceramic substrate; forming a seed layer on the predetermined position of the ceramic substrate; using direct current electroplating method or chemical plating to increase the thickness of the seed layer; forming a pattern on the seed layer using a process of film coating, exposure and development; using a plurality of direct current plating method to form a copper layer on the circuit pattern; performing multiple steps of direct current electroplating to form a copper circuit on the circuit pattern; and a process of stripping and etching.

After the steps described in foregoing two embodiments, additional steps can be performed. The additional steps include: electroplating of nickel on the copper circuit layer and electroplating of silver or gold on the nickel layer

In the foregoing embodiments, the arithmetical mean roughness (Ra) of the copper circuit is below 0.1 μm, and the ten-point mean roughness (RZ) of the copper circuit is below 1 μm.

In comparison with the conventional pulse electroplating technology, the present invention provides a preferable method to reduce roughness of the surface of the copper circuit, by using multiple steps of direct current electroplating, followed by a subsequent plating process with nickel and plating with silver or gold to greatly reduce surface roughness, so as to improve the efficiency of LED light reflection and both the yield and stability of LED die package.

### BRIEF DESCRIPTION OF THE DRAWINGS

FIG. 1 is a flow chart of a first embodiment of the present invention.

FIGS. 2a-2d are schematic cross-sectional views of the first embodiment of the present invention.

FIG. 3 is a flow chart of a second embodiment of the present invention.

FIGS. 4a-4e are schematic cross-sectional views of the second embodiment of the present invention.

FIG. 5 is a flow chart of a third embodiment of the present invention.

FIG. 6 is s a flow chart of a fourth embodiment of the present invention.

### DETAILED DESCRIPTION OF THE PREFERRED EMBODIMENTS

### First Embodiment

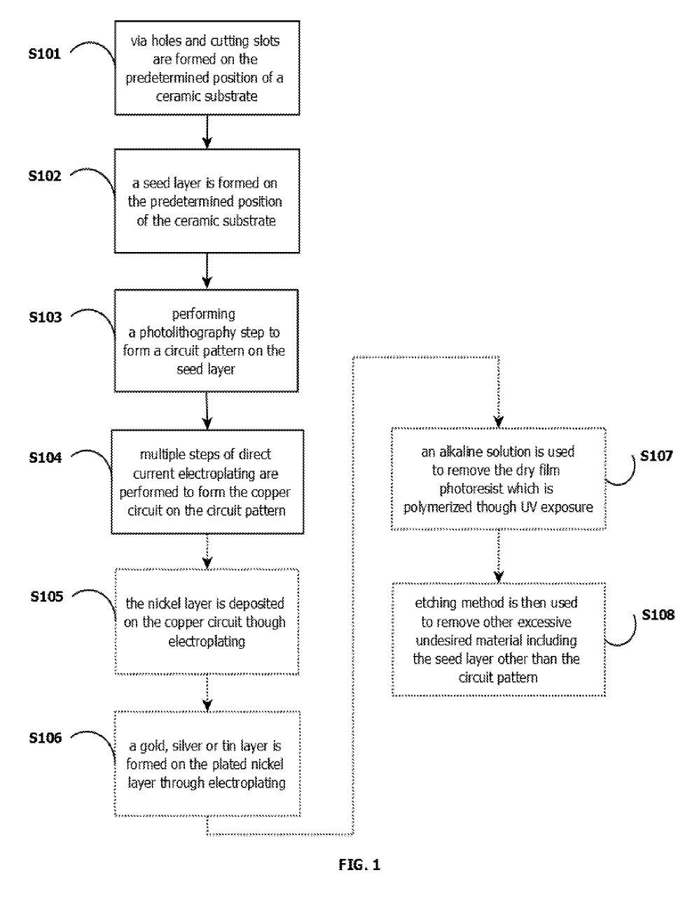

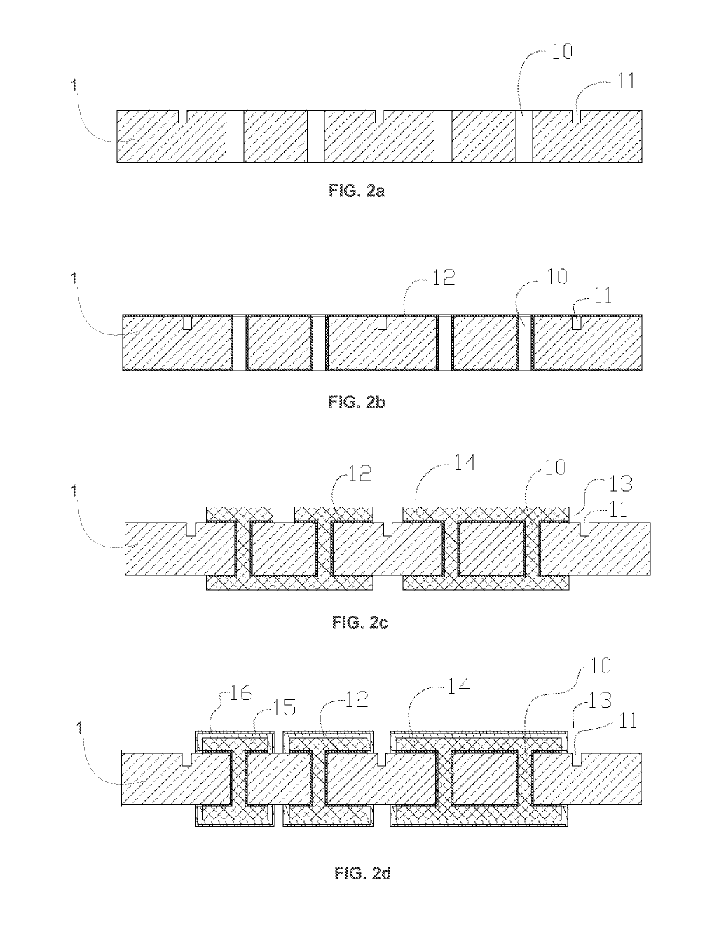

Referring to FIG. 1, and FIGS. 2a to 2d, in step S101 as shown in FIG. 2a, via holes 10 and cutting slots 11 are formed on the predetermined position of a ceramic substrate 1. In this present embodiment, the ceramic substrate 1 is an aluminium oxide substrate or aluminium nitride substrate. The via hole 10 is formed by laser drilling technology which is technically more superior than mechanical drilling, hence is used for ceramic substrate 1 with very high hardness and high demand for precision of the via holes. The cutting slot 11 can be horizontally cut, vertically cut, or in curve shape, according to practical needs, to facilitate the convenience of cutting or breaking of the ceramic substrate 1. Additionally, it should be noted that the cutting slots 11 can be optionally formed on the ceramic substrate 1.

In step S102, as shown in FIG. 2b, a seed layer 12 is formed on the predetermined position of the ceramic substrate 1. In the present invention, the seed layer 12 is formed using sputtering deposition method. Practically, sputtering deposition is used to deposit titanium or copper on the ceramic substrate 1, or deposit titanium on the substrate 1 first and then deposit copper on the titanium layer, so as to increase the adherence strength between the latter formed copper circuit layer using direct current electroplating and the ceramic substrate. The seed layer 12 can also be exemplified by sputtering nickel/copper/manganese alloy, nickel/chromium alloy, titanium/tungsten alloy, or nickel/copper alloy on the substrate 1.

It should be noted, that in other embodiments, other methods such as printing can be used to form the conductive adhesive made of conductive materials such as silver, copper or carbon, covering on the surface of the via holes 10.

In step S103, as shown in FIG. 2c, performing a photolithography step to form a circuit pattern 13 on the seed layer 12. As the patterning process is a conventional art, therefore will not be described as a flowchart.

For more details in the process, the step of forming a photo-resist layer further comprises attaching a dry film photoresist layer on the ceramic substrate using a calendaring machine. Subsequently, through exposure with UV illumination, dry film which is covered by the mask will not interacts with the UV light to undergo polymerization. The dry film is negative resin photoresist which becomes polymerized after exposure to the UV light, and remains on the surface. The use of mask to selectively expose the regions that require copper platting disposition to reveal the circuit pattern 13.

In step S104, multiple steps of direct current electroplating are performed to form the copper circuit 14 on the circuit pattern 13. The thickness of the copper circuit 14 depends on the practical needs.

The method of forming the copper circuit 14 in the present invention is to use the advantages of multiple steps of direct current electroplating of different current density for controlling the via holes' variation within unit time to achieve the desired high glossiness of the surface and overall high efficiency.

In the present embodiment, taking two step electroplating as an example, through mechanical or laser drilling method, via holes 10 with diameters of 60-80 μm are formed on a ceramic substrate 1 with a thickness of 0.38 mm, in which the aspect ratio, i.e. a ratio of the diameter of the via holes 10 to the thickness of the ceramic substrate 1, is about 1:5.

Subsequently, in the first step of DC electroplating, the density of the current is adjusted to 0.5-1.0 ASD, allowing via holes to be filled by the solution with high copper and low acid concentration.

A second step of DC electroplating is then followed, wherein the density of the current is adjusted to 3.0-4.0 ASD, to form the copper circuit 14 with a desired thickness of 50-75 μm, and Ra and Rz thereof to be below 0.1 μm and 1.0 μm, respectively.

Through the foregoing multiple steps of DC electroplating, the surface of the copper circuit 14 is glorified, thereby enhancing the efficiency of electroplating as well as reducing the possibility of undesired void defects of the via hole, without the need of grinding and polishing process to achieve the objective of gloss plating surface with reduced roughness.

It should be noted that, however in practice, the number of steps and/or the average density of the current is adjustable according to several parameters such as thickness of the ceramic substrate, the shape and/or diameter of the via hole, and the aspect ratio, in order to achieve the desired surface roughness of the copper circuit 14.

As shown in FIG. 2d, in the present embodiment and the embodiment below, after the formation of the copper circuit, step S105 through step S108 can be optionally performed. In the step S105, the nickel layer 15 is deposited on the copper circuit 14 though electroplating, followed by step S106 wherein a gold, silver or tin layer 16 is formed thereon and in order to make the copper circuit 14 to meet the requirement for die bonding and wire bonding, electroplating method is used to form the gold, silver or tin layer 16 on the surface of the copper circuit 14. Moreover, in order to avoid ion transfer between the copper ion from copper circuit 14 and the gold, silver or tin ions from the above-mentioned gold, silver or tin layer 16, a nickel layer 15 is deposited between the copper circuit 14 and the gold, silver or tin layer 16 using an electroplating method.

Subsequently, in step S107, an alkaline solution is used to remove the dry film photoresist which is polymerized though UV exposure. In step S108, etching method is then used to remove other excessive undesired material including the seed layer 12 other than the circuit pattern 13.

### Second Embodiment

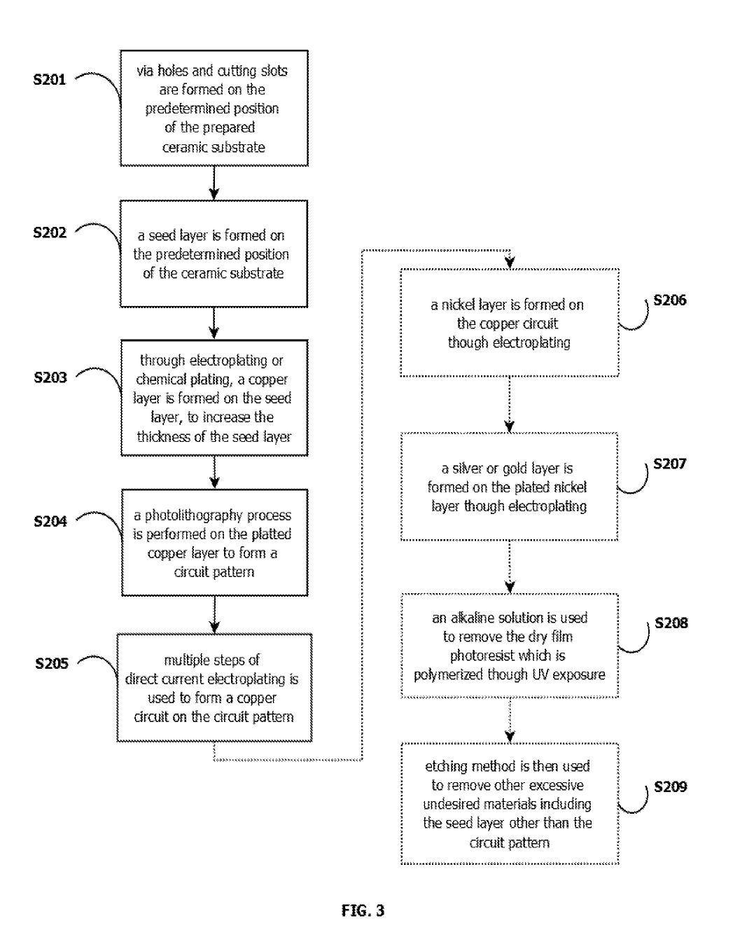

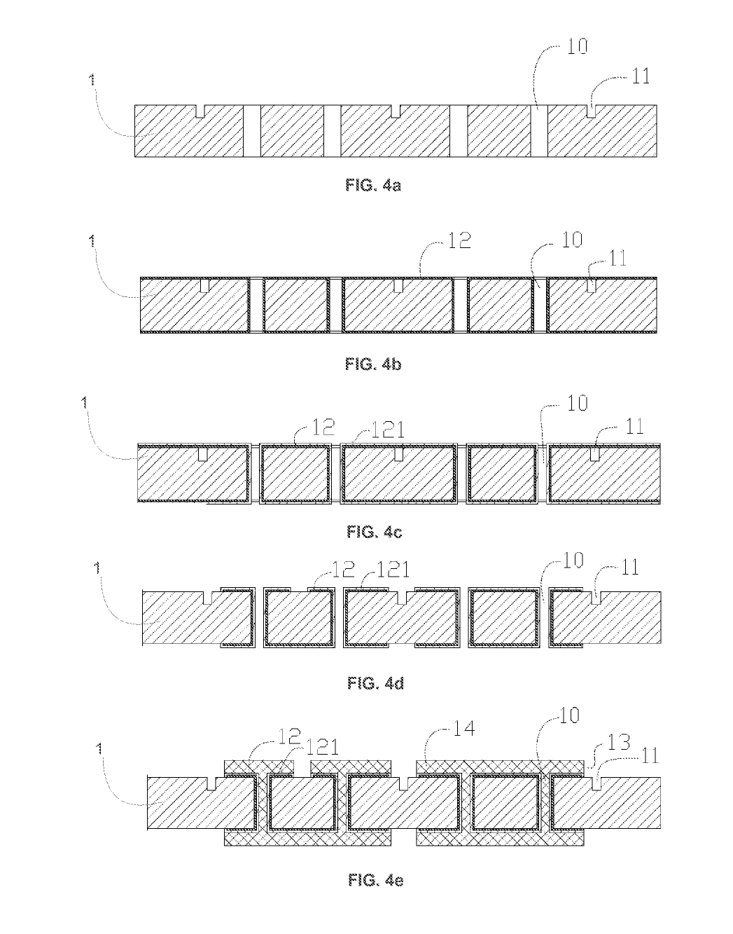

Referring to FIG. 3 and FIGS. 4a-4e, the fabricating steps of the present embodiment is substantially the same as that of the first embodiment, with slight modification of the order of the process. The part that is the same as the first embodiment will not be redundantly described herein.

In step S201, as shown in FIG. 4a, via holes 10 and cutting slots 11 are formed on the predetermined positions of the prepared ceramic substrate 1.

In step S202, as shown in FIG. 4b, a seed layer 12 is formed on the predetermined position on the ceramic substrate 1.

In step S203, as shown in FIG. 4c, through electroplating or chemical plating, a copper layer 121 is formed on the seed layer 12, to increase the thickness of the seed layer 12. As in step S202, the seed layer 12 is formed by sputtering method which is the same as in step S102 of the first embodiment, and when the diameter of the via hole 10 is too small, it is possible that the bubbles generated though sputtering can influence the quality of electrical connection of the ceramic substrate 1. Therefore, electroplating or chemical plating of a copper layer 121 on the seed layer 12 can enhance the quality of the electrical connection of the ceramic substrate 1, especially with the wall of the via hole 10.

In step S204, as shown in FIG. 4d, a photolithography process is performed on the platted copper layer 121 to form a circuit pattern 13.

In step S205, as shown in FIG. 4e, multiple steps of direct current electroplating is used to form a copper circuit 14 on the circuit pattern 13. Since the multiple steps of direct current electroplating is the same as that described in the first embodiment, which can be adjusted according to practical needs, therefore will not be described herein.

Subsequently, steps S206-209 are performed optionally. In step S206, a nickel layer is formed on the copper circuit 14 though electroplating, followed by step S207 wherein a silver or gold layer is formed on the plated nickel layer though electroplating.

After that, in step S208, an alkaline solution is used to remove the dry film photoresist which is polymerized though UV exposure. In step S209, etching method is then used to remove other excessive undesired materials including the seed layer 12 other than the circuit pattern 13.

### Third Embodiment

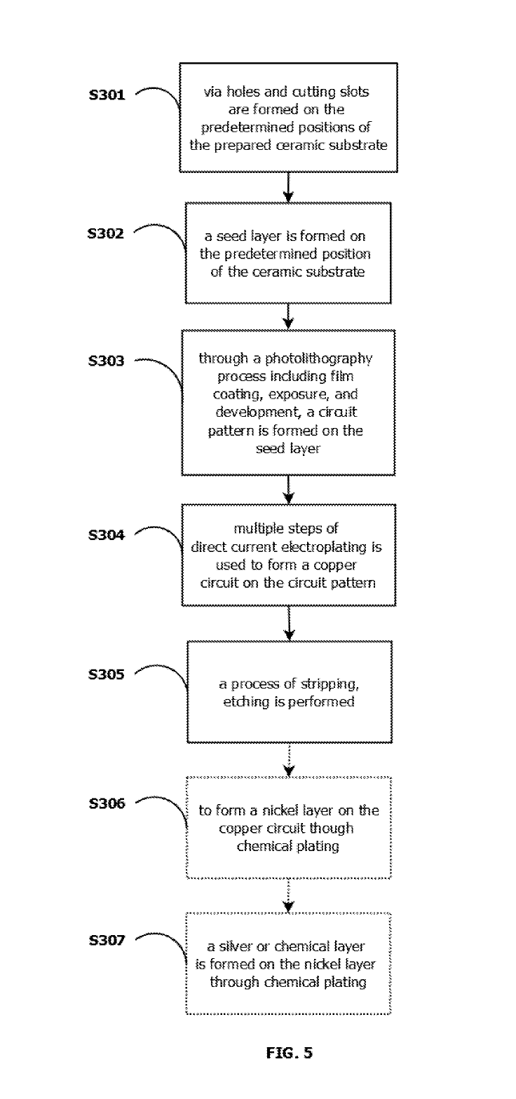

Referring to FIG. 5 the fabricating steps of the present embodiment is substantially the same as that of the first and second embodiment, with slight modification of the order of the process. The part that is the same as the first embodiment will not be redundantly described herein.

In step S301, via holes 10 and cutting slots 11 are formed on the predetermined positions of the prepared ceramic substrate 1.

In step S302, a seed layer 12 is formed on the predetermined position on the ceramic substrate 1.

In step S303, through a photolithography process including film coating, exposure, and development, a circuit pattern 13 is formed on the seed layer 12.

In step S304, multiple steps of direct current electroplating is used to form a copper circuit 14 on the circuit pattern 13. Since the multiple steps of direct current electroplating is the same as that described in the first embodiment, which can be adjusted according to practical needs, therefore will not be described herein.

In step S305, a process of stripping, etching is performed, which is the same as in step S107 and S108 as described in the first embodiment, therefore will not be described herein.

Subsequently, step S306 is optionally performed to form a nickel layer on the copper circuit 14 though chemical plating, and step S307, a silver or gold layer is formed on the Nickel layer through chemical plating.

### Fourth Embodiment

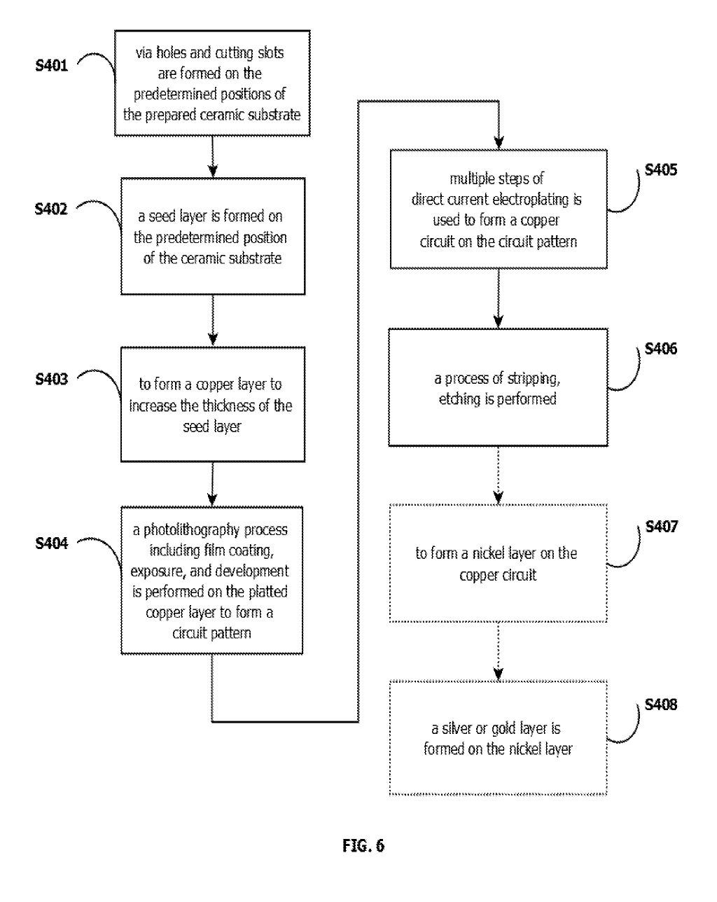

Referring to FIG. 6 the fabricating steps of the present embodiment is substantially the same as that of the first, second and third embodiment, with slight modification of the order of the process. The part that is the same as the first embodiment will not be redundantly described herein.

In step S401, via holes 10 and cutting slots 11 are formed on the predetermined positions of the prepared ceramic substrate 1.

In step S402, a seed layer 12 is formed on the predetermined position on the ceramic substrate 1.

In step S403, through the process of electroplating or chemical plating to form a copper layer 121 to increase the thickness of the seed layer 12.

In step S404, a photolithography process including film coating, exposure, and development is performed on the platted copper layer 121 to form a circuit pattern 13.

In step S405, multiple steps of direct current electroplating is used to form a copper circuit 14 on the circuit pattern 13. Since the multiple steps of direct current electroplating is the same as that described in the first embodiment, which can be adjusted according to practical needs, therefore will not be described herein.

In step S406, a process of stripping, etching is performed, which is the same as in step S107 and S108 as described in the first embodiment, therefore will not be described herein.

Subsequently, step S407 is optionally performed to form a nickel layer on the copper circuit 14 though chemical plating, and step S408, a silver or gold layer is formed on the Nickel layer through chemical plating.

In summary, the present invention discloses a method of using multiple steps of direct current electroplating to achieve a desired surface roughness of the copper circuit, combined with latter process of nickel and silver or gold plating, to increase the efficiency of light reflection of the plated silver or gold circuit as well as to reduce the surface roughness, such that the efficiency of the reflection of the LED light resource can be greatly increased, as well as the yield of the package and the stability of the product.

While certain embodiments have been described, these embodiments have been presented by way of example only, and are not intended to limit the scope of the inventions. The novel embodiments described herein may be embodied in a variety of other forms; furthermore, various omissions, modifications in the form of the embodiments described herein may be made without departing from the spirit of the inventions. The accompanying claims and their equivalents are intended to cover such forms or modifications as would fall within the scope and spirit of the inventions.

What is claimed is:

1. A method for reducing roughness of the metal surface on a ceramic substrate having via holes, comprising the steps of:
preparing a ceramic substrate;
forming at least one of a via hole and a cutting slot on the predetermined position of the ceramic substrate;
forming a seed layer on the predetermined position of the ceramic substrate;
performing a photolithography step to form a circuit pattern on the seed layer; and
performing multiple steps of direct current electroplating to form a copper circuit on the circuit pattern, wherein the Ra of the copper circuit is below 0.1 μm and Rz of the copper circuit is below 1.0 μm.

2. The method according to claim 1, wherein the seed layer is formed by sputtering plating or printing.

3. The method according to claim 1, further comprising the steps of forming a nickel layer on the copper circuit and forming a silver or gold layer on the plated nickel layer using an electroplating method.

4. The method according to claim 1, further comprising the process of stripping and etching for removing other undesired materials other than the copper circuit on the ceramic substrate.

5. The method according to claim 1, wherein the aspect ratio of a diameter of the via hole to the thickness of the ceramic substrate is 1:5.

6. The method according to claim 1, wherein in the multiple steps of direct current electroplating, further comprising a first step of direct current electroplating in which the current density is adjusted to 0.5-1.0 ASD, and a second step of direct current electroplating in which the current density is adjusted to 3.0-4.0 ASD.

7. The method according to claim 1, wherein after the step of forming the seed layer further comprising the following step:
using electroplating or chemical plating method to increase the thickness of the seed layer.

8. The method according to claim 1, wherein the steps of forming the circuit pattern further comprising:
forming a pattern on the seed layer though a process of film coating, exposure and development.

9. A method of forming a conductive circuit on a ceramic substrate, comprising the steps of:
providing a ceramic substrate;
forming a circuit pattern on the ceramic substrate; and
using multiple steps of direct current electroplating method to form a conductive circuit on the circuit pattern, wherein the density of the current in the first step is lower than that of the second step.

10. The method according to claim 9, wherein the ceramic substrate has at least one via hole.

11. The method according to claim 9, wherein prior to the step of forming the circuit pattern comprising the following step:
forming a seed layer on the ceramic substrate.

12. The method according to claim 11, wherein the seed layer is formed by sputtering plating or printing.

13. The method according to claim 11, wherein after the step of forming the conductive circuit, further comprising the process of stripping and etching for removing other undesired materials other than the conductive circuit on the ceramic substrate.

14. The method according to claim 9, further comprising the steps of forming a nickel layer on the copper circuit and forming a silver or gold layer on the plated nickel layer using an electroplating method.

15. The method according to claim 9, wherein in the multiple steps of direct current electroplating, further comprising a first step of direct current electroplating in which the current density is adjusted to 0.5-1.0 ASD, and a second step of direct current electroplating in which the current density is adjusted to 3.0-4.0 ASD.

16. The method according to claim 9, wherein the conductive circuit is a copper circuit.

17. The method according to claim 16, wherein Ra of the copper circuit is below 0.1 μm and Rz of the copper circuit is below 1.0 μm.

18. A ceramic substrate, comprising a copper circuit formed by multiple steps of direct current electroplating, wherein the copper circuit has Ra below 0.1 μm and Rz below 1.0 μm without a further process after the multiple steps of direct current electroplating.

19. The ceramic substrate according to claim 18, comprising at least one via hole.

20. The ceramic substrate according to claim 18, being a heat dissipated substrate of a Light Emitted diode (LED).
